(19) United States
(12) Patent Application Publication
(10) Pub. No.: US 2008/0206104 A1
(43) Pub. Date: Aug. 28, 2008

(54) Accurate Magnetic Biosensor

(75) Inventors: Menno Willem Jose Prins, Eindhoven (NL); Albert Hendrik Jan Immink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/917,211

(22) PCT Filed: Jun. 12, 2006
(86) PCT No.: PCT/IB06/51866

§ 371 Date: Dec. 12, 2007

(30) Foreign Application Priority Data
Jun. 17, 2005 (EP) 05105361.9

(51) Int. Cl. B01J 19/00; G01R 33/09

(52) U.S. Cl. 422/82.01; 422/68.1; 324/252

(57) ABSTRACT

The invention provides a method, a device and a system for determining the concentration of at least one sort of targets in a fluid containing at least one sort of polarizable of polarized magnetic labels in a fluid, the sensing surface comprising at least one sort of binding sites capable to specifically attach to at least one sort of biological entities linked to the magnetic labels, the sensing device further comprising at least one magnetic sensor element, the sensing device further comprising distinction means for time-resolved distinguishing between magnetic labels specifically attached to the binding sites versus labels non-specifically attached. The method and device according to the present invention may be applied to biomolecular diagnostics.

The present invention relates to a sensing device and to a system for determining the concentration of at least one sort of targets in a fluid containing at least one sort of polarizable or polarized magnetic labels, the system comprising the sensing device. The present invention further relates to a method for determining a concentration of at least one sort of polarizable or polarized magnetic labels in a fluid using the sensing device.

In the field of diagnostics especially in biomedical diagnostics, such as medical and food diagnostics for both in vivo and in vitro application, but also for animal diagnostics, diagnostics on health and disease, or for quality control, the usage of biosensors or biochips is well known. These biosensors or biochips are generally used in the form of micro-arrays of biochips enabling the analysis of biological entities as e.g. DNA (desoxyribonucleic acid), RNA (ribonucleic acid), proteins or small molecules, for example hormones or drugs. Nowadays, there are many types of assays used for analysing small amounts of biological entities or biological molecules or fragments of biological entities, such as binding assays, competitive assays, displacement assays, sandwich assays or diffusion assays. The challenge in biochemical testing is presented by the low concentration of target molecules (e.g. pmol.l⁻¹ and lower) to be detected in a fluid sample with a high concentration of varying background material (e.g. mmol.l⁻¹). The targets can be biological entities like peptides, metabolites, hormones, proteins, nucleic acids, steroids, enzymes, antigens, haptens, drugs, cell components, or tissue elements. The background material or matrix can be urine, blood, serum, saliva or other human-derived or non-human-derived liquids or extracts. Labels attached to the targets improve the detection limit of a target. Examples of labels are optical labels, coloured beads, fluorescent chemical groups, enzymes, optical barcoding or magnetic labels.

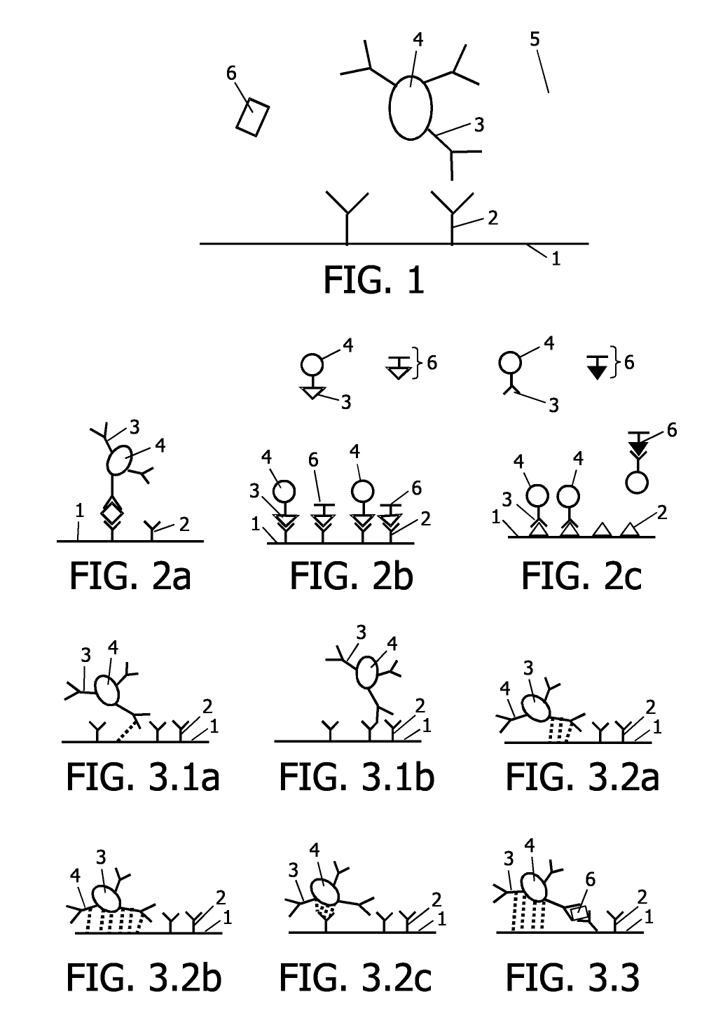

Biosensors generally employ a sensing surface 1 with specific binding sites 2 equipped with capture molecules. These capture molecules can specifically bind to other molecules or molecular complexes present in the fluid. Other capture molecules 3 and labels 4 facilitate the detection. This is illustrated in FIG. 1, which shows a biosensor sensing surface 1 to which capture molecules are coupled providing binding sites 2 to other biological entities, e.g. the target molecules 6 or targets 6. In solution 5, targets 6 and labels 4 to which further capture molecules 3 are coupled are present.

Targets 6 and labels 4 are allowed to bind to the binding sites 2 of the biosensor sensing surface 1 in a specific manner which is hereinafter called “specifically attached”. However, other binding configurations are also possible, which are herinafter called “non-specifically attached”. In FIGS. 2a, 2b, 2c, 3.1a, 3.1b, 3.2a, 3.2b, 3.2c, 3.3 some examples of possible binding configurations of labels 4 to a biosensor sensing surface 1 are illustrated. FIGS. 2a and 2b represent the so called Type 1 binding configurations which realise the desired biological attachment. In FIG. 2a, a desired biological attachment is shown in which the target molecule 6 is sandwiched between the binding site 2 on the biosensor sensing surface 1 and a capture molecule 3 present on a label 4 (sandwich assay). In FIG. 2b, the case of a competitive assay biosensor is shown, where the binding sites 2 provided on the sensing surface 1 are able to attach both the labels 4 (by attaching the binding sites 2 to the capture molecules 3 equipped with the labels 4) and as well the targets 6. The targets 6 have, at least partially and in respect of the binding sites 2, a form and/or a behaviour similar to the capture molecules 3 such that there is a competition for binding sites 2 between the capture molecules 3 (i.e. the labels 4) and the targets 6. In FIG. 2c, the case of an inhibition assay biosensor is shown, where the binding sites 2 are biologically similar to the targets 6 and where the labels 4 are bound to capture molecules 3 (or in general biological entities) that can either bind to the targets 6 or to the binding sites 2. Ideally, a target 6 bound (via a capture molecule 3) to a label 4 can no longer bind to the binding surface 2.

In the figures, bio-active entities (e.g. capture molecules 3 or binding sites 2) are sketched as being directly coupled to a solid carrier (e.g. sensor surface 1 or label 4). As is known in the art, such bio-active layers are generally linked to a solid carrier via intermediate entities, e.g. a buffer layer or spacer molecules. Such intermediate entities are added to achieve a high density and high biological activity of molecules on the surface. For clarity and simplicity, the intermediate entities are omitted in the figures.

In contrast to this biological attachment to the sensing surface 1, labels 4 can also attach to the sensing surface 1 in a non-specific or non-biological manner, i.e. bind to the surface 1 without mediation of the specific target molecules 6. FIGS. 3.1a, 3.1b, 3.2a, 3.2b, 3.2c, 3.3 represent such a non-biological attachment with FIGS. 3.1a and 3.1b showing examples of a so called Type 2 binding configuration where a single non-specific bond exists between a capture molecule 3 coupled to the label 4 and the biosensor sensing surface 1 and/or between a capture molecule 3 coupled to the label 4 and a binding site 2 coupled to the biosensor sensing surface 1. Normally, such a Type 2 binding by only one single non-specific bond is only weak and can be removed by stringency procedures such as washing or magnetic forces. As represented in FIGS. 3.2a, 3.2b and 3.2c, a so called Type 3 binding configuration to the sensing surface 1 and/or to the binding site 2 is also possible via a multitude of non-specific bonds across a larger area between the labels 4 (or the capture molecule 3 coupled to the labels 4) on the one hand and the biosensor sensing surface 1 and/or the bindings sites 2 on the other hand. Type 3 configurations usually provide a stronger binding force than Type 1 bonds. FIG. 3.3 shows a degenerate version of Type 1, where the label 4 is bound to the biosensor sensing surface 1 by specific as well as non-specific bonds.

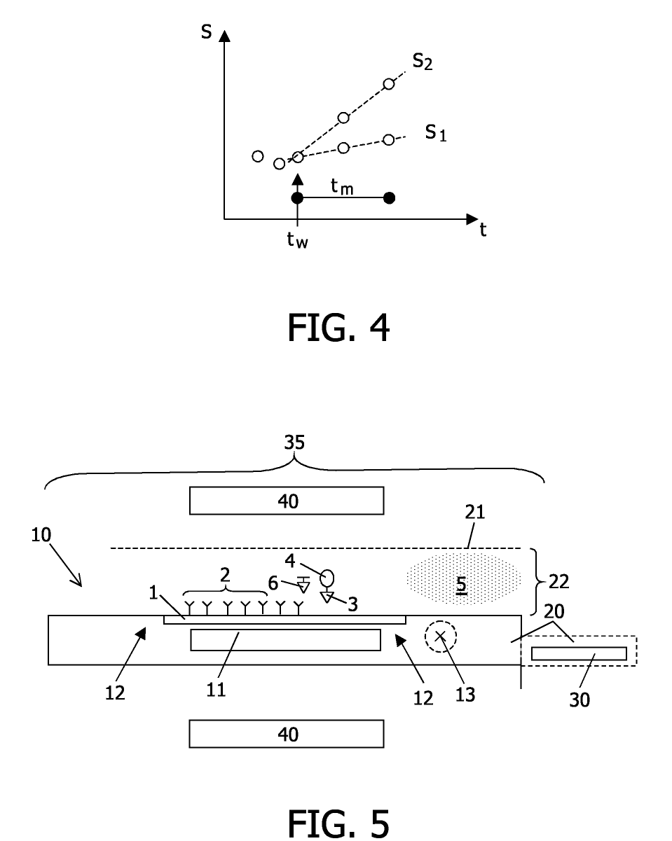

In point-of-need testing, e.g. roadside through-the-window testing of drugs-of-abuse in saliva, e.g. for traffic safety, it is essential to provide for a testing equipment sufficiently robust to be used on a day-to-day basis and to provide for a testing method yielding results that are sufficiently quick and precise. Such testing can be performed in several formats, e.g. in a competitive or in an inhibition assay format. In FIG. 4, the development over time of the target-dependent sensor signals S₁ and S₂ for two different test samples is shown, where signal S₁ corresponds to a high target 6 concentration and signal S₂ corresponds to a low target 6 concentration. The differences in S₁ versus S₂ is due to the fact that the lower the concentration of target molecules in the test sample the higher is the probability of labels 4 attached to capture molecules 3 to bind to the binding sites 2 of the sensing surface 1.

In the international patent application WO 03/054566 A1, a magnetoresistive sensing device for determining a density of magnetic particles in a fluid is disclosed. The magnetoresistive sensing device or biochip has a substrate with a layer structure supporting a fluid. The layer structure has a first surface area in a first level and a second surface area in a second level and a magnetoresistive sensing element for detecting the magnetic field of at least one magnetic particle in the fluid. The magnetoresistive element is positioned near a transition between the first and second surface area and faces at least one of the surface areas. With such a device it is possible to determine the concentration of labels 4 in the fluid.

It is an object of the present invention to provide a sensing device, a system and a method, which is able to determine the concentration of at least one sort of targets in a fluid containing at least one sort of polarizable or polarized magnetic labels in a manner that is sufficiently quick and accurate, especially by using the concentration of at least one sort of polarizable or polarized magnetic labels in a fluid and especially by accurately measuring the exposure rate of a sensing surface to magnetic labels as well as the concentration of specifically bound magnetic labels on a sensing surface.

The above objective is accomplished by a sensing device, a system and a method according to the present invention.

In a first aspect of the present invention, a sensing device is provided for determining the concentration of at least one sort of targets in a fluid containing at least one sort of polarizable or polarized magnetic labels. The sensing device comprises at least one sensing surface, the sensing surface comprises at least one sort of binding sites capable of specifically attaching to at least one sort of biological entities linked to the magnetic labels. The sensing device further comprises at least one magnetic sensor element, the sensing device further comprises distinction means for distinguishing between magnetic labels specifically attached to the binding sites versus labels non-specifically attached in a manner that is time-resolved.

An advantage of the device according to the invention is that it allows to determine the concentration of the target molecules in an assay on a magnetic biosensor more accurately and more rapidly than previously known. It was totally surprising and could not have been expected by a person skilled in the art that it is possible to improve the detection limit and the specificity with the sensing device according to the invention by accurately determining the concentration of labels directly above the sensor surface and during the time that the binding process takes place on the sensing surface.

We will discuss the present invention for a range of different assays. In the first example, the present invention is discussed for the case of an inhibition assay. A sample with targets 6 is exposed to a reagent with labels 4. The labels 4 are provided with capture molecules 3. In this case, these capture molecules 3 can be regarded as being biological capture molecules 3 such as anti-target antibodies that can specifically bind to targets 6. Due to their rapid kinetics, the targets 6 bind to the labels 4 via capture molecules 3. Depending on the target concentration and the binding properties of the capture molecules 3 (e.g. association and dissociation constants), the capture molecules 3 on the surface of the label 4 are bound to a larger or lesser extent with targets 6. The coverage fraction of capture molecules 3 is represented by a parameter ε. In this assay, we call this parameter the inhibition fraction and it ranges between 0% and 100%. In case the assay is tuned to be target-limited, i.e. when the assay is in a sensitive regime, the parameter can be proportional to the target concentration in the sample. Now the sensor surface 1 is coated with binding sites 2, in this case target-like molecules, e.g. drug conjugates. The fluid with labels 4 is in contact with the sensor surface 1. Magnetic labels 4 that can freely move in the solution have a first chance to approach the sensor surface, a second chance to come into biological contact with the sensor surface and a third chance to bind to the binding sites 2 on the sensor surface 1. The rate at which labels 4 approach and contact the sensor surface is called the exposure rate. The exposure rate does not or only very little depend on the concentration of targets in the fluid. This is in strong contrast to the binding rate, which strongly depends on the concentration of targets in the fluid, e.g. via parameter ε. The exposure rate is always higher than the binding rate, and generally much higher than the binding rate.

The rate of exposure and binding of labels 4 to the sensor surface depends on many parameters. Some of the parameters are easy to control or calibrate before the time of test, and other parameters can strongly vary depending on the conditions of the test and of the properties of the sample fluid. For example, the area A of the sensor surface is very precisely set in the fabrication process, e.g. due to the masks and lithographic processing of the chip. Also, the biological properties of the binding sites 2 and capture molecules 3 (e.g. surface density, and biological activity such as association and dissociation properties) can be controlled and/or calibrated beforehand in the bio-fabrication process of the device or thereafter. However, the exposure rate of the sensor surface 1 by labels 4 is difficult to control or calibrate, because it depends on many parameters such as the number of labels in the reagent that was brought in contact with the sample, the solvation rate of the reagent into the sample (note that the reagent can be supplied in fluid or in dry form), the viscosity of the sample, the temperature of the sample, the effectiveness of mixing and/or actuation of labels in the fluid (e.g. by thermal diffusion, sedimentation, magnetic forces, acoustic forces, mechanical actuators, shear forces, rotational excitation).

In the above inhibition format, the binding of targets 6 to labels 4 partially or totally inhibits the binding of labels 4 to the target-like binding sites 2. The rate of specific binding dN/dt of labels 4 to binding sites 2 on the sensor surface 1 is approximately given by (unit s⁻¹):

$$\frac{d N}{d t} = {Ak}_{on} [ Cap ] [ L ] ( 1 - ɛ ) ⇔ ɛ = 1 - \frac{d N / d t}{{Ak}_{on} [ Cap ] [ L ]} \qquad ( 1 )$$

with A the area of the sensor surface (unit m²), kₒₙ, the association constant of the molecular binding process (unit m³/s), [Cap] the concentration of binding sites on the sensor surface (unit m⁻²), [L] the concentration of labels 4 in the fluid (unit m⁻³), especially a solution, in the vicinity of the sensor, and ε the inhibition fraction which depends on the target concentration in the sample. The association constant kₒₙ depends on the biological materials and on other kinetic conditions (e.g. temperature, or forces that are applied to the labels during the binding process, e.g. magnetic forces), which can be controlled and/or calibrated during or after the bio-fabrication process of the device, or even just before the test with a calibration fluid (for simplicity and for purposes of clarity, we have neglected the dissociation process, k_{off}, in the equation).

The goal of the test is to accurately measure the concentration of targets in the original sample, which has a well-defined relationship with the parameter ε. So we need to determine the parameter ε with high precision, i.e. with low Δε/ε. In view of the above equation, it is important to determine all other parameters in, i.e. dN/dt, A, kₒₙ, [Cap] and [L], with high accuracy. This is particularly challenging in the case of small target concentration: in that case, ε is small and uncertainties in all other parameters strongly degrade the precision of ε.

It is therefore necessary that in a fluid, the exposure rate of the sensor surface to labels 4 is accurately known. In this invention, it is proposed to determine the exposure rate via a measurement of the volume density of magnetic particles functioning as magnetic labels with very high accuracy. According to the present invention, the volume density of the magnetic labels or beads is ideally determined directly above the sensor and measured while the test is taking place. However, the volume density can also be measured at a somewhat different location or time, as long as the measurement is representative of the factual volume density above near the binding sites. Therefore, the sensing surface 1 is to be understood in the context of the present invention as being the place where both the measurement of the specifically attached labels 4, i.e. the binding sites 2, are located and where the measurement of the volume density of magnetic labels 4 (i.e. the non-specifically attached labels 4) for the determination of the exposure rate takes place. Furthermore, regarding the measurement of the exposure rate, i.e. the measurement of the volume density of non-specifically attached magnetic labels 4, the term “time-resolved” measurement is to be understood as not necessitating a repeated measurement of the volume density of labels during the time interval where a sampling of the sensor signal (i.e. the signal indicative of the magnetic labels specifically attached to the sensing surface)

Now we give a second example of a biological assay, namely a competition assay. The components of a competition assay are described in FIG. 2b. The rate of specific binding dN/dt of labels 4 to binding sites 2 on the sensor surface 1 is approximately given by Eq. (1), but now ε is the fractional occupation of binding sites 2 by targets 6. As in the first example, accurate and rapid data on the concentration of targets 6 in the fluid can be extracted by measuring the exposure rate of a sensing surface to magnetic labels as well as the concentration of specifically bound magnetic labels on a sensing surface.

In a third example, we present a sandwich assay. As in FIG. 1, labels 4 with capture molecules 3 are brought into contact with a sample containing targets 6, and these materials are brought into contact with binding sites 2. The desired type of specific binding is shown in FIG. 2a. Note that capture molecules 3 and binding sites 2 are generally antibodies; generally these are not the same molecules, because they bind to different parts of the targets 6. The binding type of FIG. 2a can occur in different sequences, e.g. targets 6 can first bind to labels 4 and then to binding sites 2, or vice versa. For clarity of the present description, we assume here that the targets 6 first bind to the labels 4. Depending on the target concentration and the binding properties of the capture molecules 3 (e.g. association and dissociation constants), the capture molecules 3 on the surface of the label 4 are bound to a larger or lesser extent with targets 6. The coverage fraction of capture molecules 3 by targets 6 is represented by a parameter ε. In this assay, we call this parameter the coating fraction. The binding rate dN/dt of labels 4 to binding sites 2 on the sensor surface 1 is approximately given by (unit s⁻¹):

$$\frac{d N}{d t} = {Ak}_{on} [ Cap ] [ L ] ɛ ⇔ ɛ = \frac{d N / d t}{{Ak}_{on} [ Cap ] [ L ]} \qquad ( 2 )$$

with A the area of the sensor surface (unit m²), kₒₙ the association constant of the molecular binding process (unit m³/s), [Cap] the concentration of binding sites on the sensor surface (unit m⁻²), [L] the concentration of labels 4 in the fluid (unit m⁻³), especially a solution, in the vicinity of the sensor, and ε the coating fraction which depends on the target concentration in the sample [note the difference with Eq. (1), which has the term (1−ε)]. The association constant kₒₙ depends on the biological materials and on other kinetic conditions during the test (e.g. temperature, magnetic forces), which can be controlled and/or calibrated during the bio-fabrication process or just before the test.

In the above example, the parameter ε is the coating fraction on the label 4. In case a sequential assay is done, namely first bringing the targets 6 into contact with the binding sites 2, and thereafter bringing the sensor surface 1 into contact with the labels 4, the parameter ε corresponds to the fractional occupancy of binding sites 2 by targets 6.

A fourth example of an assay that can be used, is the anti-complex assay. This assay uses the components of FIG. 1, with the special property that binding site 2 is selected to bind to capture molecule 3 in the presence of target 6, but not to capture molecule 3 alone. This format is suited for small-molecule detection, characterized in that the amount of bound labels 4 increases with the number of targets 6. In a sensitive regime of the assay, Eq. (2) can be applied.

A fifth example to demonstrate the use of this invention in an assay, is an assay with a selective blocking agent. This assay format is hereinafter also called blocking agent assay. In this assay, in addition to the components of FIG. 1, a blocking agent is used. The blocking agent can for example be a target-like molecule coupled to a larger entity. In absence of targets 6, the blocking agents will attach to the capture molecules 3, thereby blocking the binding of labels 4 to the binding sites 2. When targets are present, these will partially or totally coat the capture molecules 3. Now the labels 4 can bind to the binding sites 2. This binding can include binding to the targets 6 (as in FIG. 2a), but this is not necessary. The binding can also occur to parts of the capture molecule 3, provided that this binding does not occur when blocking agent is bound to capture molecule 3.

The amount of bound labels 4 increases with the concentration of targets 6 in the fluid sample. In a sensitive regime of the assay, Eq. (2) can be applied. This format is suited for large as well as small molecules. Small molecules can for example be drugs of abuse.

In biological assays, reagents can be put together at once (e.g. in a well of a microtiter plate) or be brought into contact sequentially in time (e.g. in a well using sequential pipetting steps, or in a lateral-flow device). For example, one can first bring targets 6 and capture molecules 3 in contact, and thereafter bring the materials in contact with the blocking agents. For enhanced speed, the materials can be brought into contact at once. A disadvantage of the latter could be that the blocking agents bind to the capture molecules 3 before the targets 6 can bind to the capture molecules 3, thereby reducing the coating fraction ε. This will reduce the binding rate of labels 4 to the binding sites 2. However, in case of rapid molecular kinetics, the targets 6 can displace blocking agents bound to capture molecules 3, so the coating fraction ε is little affected.

The assay examples described above demonstrate that the measured binding rate of labels 4 to the sensing surface 1 depends on the concentration of targets 6 in the fluid. The present invention claims that the concentration of at least one sort of targets 6 can more accurately, and therefore also more rapidly, be deduced from the measured rate of specific binding of labels 4 to the binding sites 2 by in addition measuring the exposure rate of labels 4 to the binding sites 2.

This was illustrated by kinetic equations involving a fractional parameter ε, which relates to the concentration of targets 6.

In a preferred embodiment, the exposure rate is determined by measuring the concentration of labels 4 in the vicinity of the surface 1.

In a preferred method, the concentration of targets 6 is determined by calculating the ratio of binding rate versus exposure rate. More preferred, the concentration of targets 6 is determined by calculating the ratio of measured specific binding rate versus measured concentration of labels 4 in the vicinity of the binding sites 2.

In general, a sensing device will be sensitive to labels specifically attached to the sensing surface (Type 1 binding, cf. above) as well as to labels that are not specifically attached but still in the vicinity of the sensing surface. This second alternative can be realised either by label binding to the sensing surface in the manner of Type 2 or by labels not attached to the sensing surface, but being located in the vicinity of the surface.

According to the present invention, these different magnetic label concentrations are measured independently. According to one embodiment of the invention, it is, for example, possible to differentiate the specifically attached magnetic labels from other labels through their differences of rotational and/or translational mobility of labels specifically attached versus labels non-specifically attached versus labels that are not attached. For example, it is possible to apply magnetic fields and to determine mobility-dependent signals. Such magnetic fields can also be modulated, e.g. by current wires or magnets, to attract magnetic labels to the sensing surface, or to repel magnetic labels from the sensing surface, or to move magnetic labels over the sensing surface. A comparison of the signal of the magnetic sensor element for the different positions of the magnetic labels allows a determination of the number of mobile magnetic labels in the vicinity of the sensing surface that are present in the solution to measure.

In a preferred embodiment of the present invention, the distinction means comprise magnetic field generating means for generating a magnetic field. The magnetic field generating means may be located on the sensor device and may for example be a current wire or a two-dimensional wire structure. The magnetic field generating means may generate a rotating magnetic field. In another embodiment, the magnetic field generating means may generate a unidirectional or one dimensional magnetic field, e.g. a pulsed unidirectional magnetic field, or a sinusoidally modulated magnetic field. In this case, the different motional or rotational freedom of magnetic labels differently bound to the sensing surface may be related to the different speed of translation of a first group of magnetic labels in a certain direction through a fluid, e.g. liquid or a gas, or may be related to the different rotational speed of such a group of magnetic labels. In this way, different groups of magnetic labels can be differentiated or distinguished by means of the inventive sensing device.

In a further preferred embodiment of the present invention, the distinction means of the sensing device comprise two magnetic field generating means positioned at each side of one magnetic sensor element, i.e. left and right or above and below. Alternatively, the sensor element is positioned in between two current lines, e.g. parallel current sheets. An advantage of this kind of embodiments of the present invention is that the magnetic sensor element is partially or completely insensitive to the magnetic field of the two magnetic field generating means, provided, that the two magnetic fields compensate each other to a certain extent at the location of the sensor element. Therefore, the magnetic sensor element essentially feels the magnetic field due to the presence of magnetic labels on the sensing surface or in the vicinity of the sensing surface. By placing the magnetic sensor element in a volume where the net magnetic field to which the sensor element is sensible is compensated by the two magnetic field generating means, possible saturation of the sensor element is avoided. This is particularly important in the sensitive direction of the sensor, i.e. for in-plane components of the magnetic field.

In a further preferred embodiment of the present invention, the magnetic field generating means is a two-dimensional wire structure located on the sensing device.

As previously described, a sensing device will be sensitive to labels specifically attached to the sensing surface (Type 1 binding) as well as to labels that are not specifically attached but still in the vicinity of the surface, e.g. Type 2 label binding or labels not attached to the sensing surface, but in the vicinity of the sensing surface. According to the present invention, these different magnetic label concentrations are measured independently. According to a further embodiment of the invention, the sensing device comprises the distinction means having a first surface area in a first level and a second surface area in a second level, wherein the magnetic sensor element is positioned near a transition between the first and the second area and facing at least one of the surface area. In this embodiment of the sensing device, it is preferred that the magnetic sensor element is centered around the transition between the first and second level seen in substantially perpendicular projection.

It is an advantage of the sensing device according to the second embodiment of the invention that the concentration of magnetic labels near the sensing surface is accessible only by means of a change of the geometrical shape of the sensing surface, therefore not necessitating the use of permanent or modulated magnetic fields. By this, further parameters of label binding to the sensing surface are more easily accessible or the time resolution of such measurements is enhanced.

In a further preferred embodiment of the present invention, the distinction means of the sensing device comprise a capacitive sensor means. One preferred way to measure [L] according to the invention is by capacitive detection, i.e. measuring an impedance spectrum and by taking the signal that is sensitive to the label-concentration in the solution. For this objective, the distinction means comprise a capacitive sensing means. A capacitive sensing means can be provided by means of two electrodes, e.g. capacitor plates or wires, on or above the sensing surface or in the vicinity of the sensing surface. The capacitor plates can be provided as metallized areas on or nearby the sensing surface. Alternatively, the capacitor plates can be provided in form of areas of a semiconductor material such as silicon, polysilicon or any other suitable material. The capacitor plates can be arranged substantially parallel to the plane of a substrate of the sensing device. The capacitor plates can be positioned substantially opposite to one another in a direction normal to the plane of the substrate. This has the advantage, that an important sample volume is covered or taken into account for the capacitive measurement of [L]. Alternatively, the capacitor plates can be positioned substantially opposite to one another in a direction parallel to the plane of the substrate. This has the advantage, that the capacitor plates can be manufactured substantially in the same plane as the sensing surface 1 which reduces the complexity of the manufacturing process of the sensing device.

In a still further embodiment of the present invention, the aforementioned embodiments of the present invention can also be combined in that the distinction means comprise the magnetic field generating means for generating a magnetic field and as well a first surface area in a first level and a second surface area in a second level, wherein the magnetic sensor element is positioned near a transition between the first and the second surface area and facing at least one of the first and second surface areas.

It is an advantage of the sensing device according to the third embodiment of the invention that the concentration of magnetic labels near the sensing surface is even better accessible because it is possible to combine the different measurement principles of the first and second embodiments of the present invention in order to enhance time resolution and/or accuracy of the sensing device.

For all embodiments of the sensing device, the magnetic sensor element may be one of an AMR, a GMR or a TMR sensor element. Of course, magnetic sensor elements based on other principles like Hall sensor elements or SQUIDs are also possible according to the present invention.

In the following, the present invention will mainly be described with reference to magnetic labels, also called magnetic beads or beads. The magnetic labels do not necessarily be spherical in shape, but may be of any suitable shape, e.g. in the form of spheres, cylinders or rods, cubes, ovals etc. or may have no defined or constant shape. By the term “magnetic labels”, it is understood that the labels include any suitable form of one magnetic particle or more magnetic particles, e.g. magnetic, diamagnetic, paramagnetic, superparamagnetic, ferromagnetic, that is any form of magnetism which generates a magnetic dipole in a magnetic field, either permanently of temporarily. For performing the present invention, there is no limitation on the shape of the magnetic labels, but spherical labels are the presently easiest and cheapest to manufacture in a reliable way. The size of the magnetic labels is not per se a limiting factor of the present invention. However, for detecting interactions on a biosensor, small sized magnetic labels will be advantageous. When micrometer-sized magnetic beads are used as magnetic labels, they limit the downscaling because every label occupies an area of at least 1 μm². Furthermore, small magnetic labels have better diffusion properties and generally show a lower tendency to sedimentation than large magnetic beads. According to the present invention, magnetic labels are used in the size range between 1 and 3000 nm, more preferably between 5 and 500 nm.

In the present description and claims of the invention, the term “biological entities” should be interpreted broadly. It includes bioactive molecules such as proteins, peptides, RNA, DNA, lipids, phospholipids, carbohydrates like sugars, or similar. The term “biological entities” also includes cell fragments such as portions of cell membranes, particularly portions of cell membranes which may contain a receptor. The term biological entities also relates to small compounds which potentially can bind to a biological entity. Examples are hormones, drugs, ligands, antagonists, inhibitors and modulators. The biological entities can be isolated or synthesized molecules. Synthesized molecules can include non-naturally occurring compounds such as modified aminoacids or nucleotides. The biological entities can also occur in a medium or fluid such as blood or serum or saliva or other body fluids or secretions, or extracts, or tissue samples or samples from cell cultures, or any other samples comprising biological entities such as food, feed, water samples or other.

The present invention also includes a system for determining the concentration of at least one sort of targets in a fluid containing at least one sort of polarizable or polarized magnetic labels, the system comprising a magnetoresistive sensing device according to any of the previously described embodiments. The system comprises the sensing device together with suitable mechanical environment like packages, chambers, channels, tubes or the like for sample taking, sample pretreatment, wetting of the sensing surface, etc. The system further comprises the sensing device together with suitable electrical and/or electronical environment like power supply, data collection and analysing means, output means.

The present invention also includes a method for determining the concentration of at least one sort of targets in a fluid containing at least one sort of polarizable or polarized magnetic labels using the sensing device according to any of the previously described embodiments of the sensing device, the method comprising the steps of:

providing a fluid comprising magnetic labels over the sensing surface,

applying a magnetic field,

time-resolved distinguishing between magnetic labels specifically attached to the binding sites versus labels not attached and/or non-specifically attached.

According to the invention, it is particularly preferred to determine the concentration of targets by calculating the ratio of the concentration of labels specifically attached versus the concentration of labels not attached, i.e. the ratio of the binding rate (represented by the concentration of the magnetic labels on the sensor surface) versus the rate of exposure (represented by the concentration of the magnetic labels in the bulk of the liquid). The concentration of targets according to the invention is proportional to the parameter ε, a parameter that represents the fractional occupancy of binding moieties, which are present on label 4 or on sensor surface 1, depending on the type of assay. This parameter is related to the target concentration in the fluid, in a manner that depends on the assay.

The central idea of the present invention is to measure the concentration of targets from two measurements, namely (i) the specific binding rate of labels to the binding sites and (ii) the exposure rate of labels to the binding sites. The exposure rate is preferably measured via the concentration of unbound labels in the vicinity of the sensor surface, i.e. [L]. There are different ways to measure [L]. One way to measure [L] is by measuring a signal that is specific for labels with high mobility. Another way to determine [L] is by comparing sensor signals for two different situations, namely a situation when unbound labels are in the sensitive region of the sensor and a situation when labels are moved away from the sensitive region of the sensor, e.g. moved away by magnetic forces, by thermal diffusion, by fluid flow, or by other transport mechanisms.

These and other characteristics, features and advantages of the present invention will become apparent from the following detailed description, taken in conjunction with the accompanying drawings, which illustrate, by way of example, the principles of the invention. The description is given for the sake of example only, without limiting the scope of the invention. The reference figures quoted below refer to the attached drawings.

FIG. 1 illustrates a biosensor to which first capture molecules are coupled in a solution comprising targets and labels to which second capture molecules are coupled.

FIGS. 2a, 2b, 2c, 3.1a, 3.1b, 3.2a, 3.2b, 3.2c, 3.3 illustrate some examples of possible binding configurations of labels 4 to a biosensor sensing surface.

FIG. 4 illustrates the time development of sensor signals for two different test samples of high target concentration and low target concentration.

FIG. 5 illustrates a schematic representation of system and a sensing device according to the present invention.

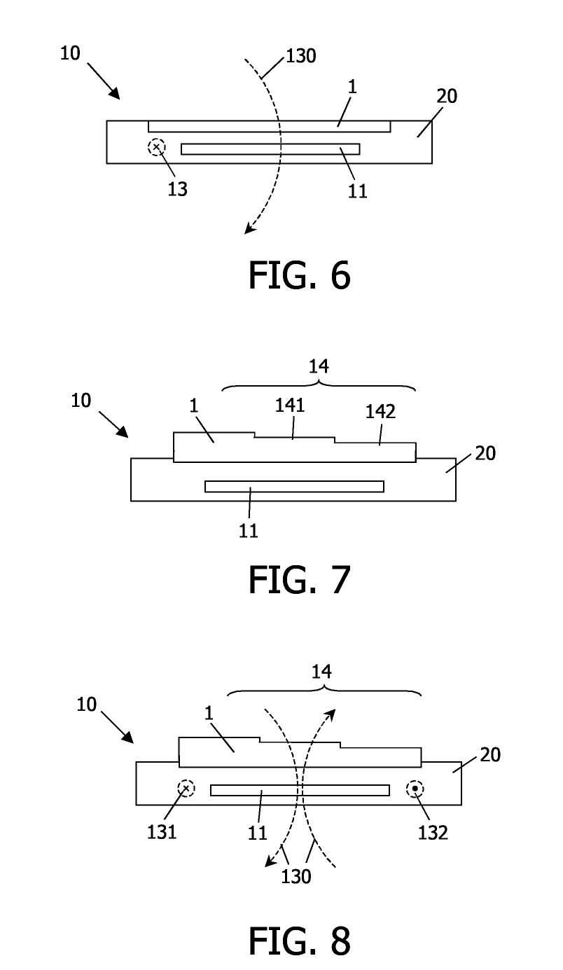

FIG. 6 illustrates a schematic representation of a device according to the first embodiment of the present invention.

FIG. 7 illustrates a schematic representation of a device according to the second embodiment of the present invention.

FIG. 8 illustrates a schematic representation of a device according to the third embodiment of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

Where an indefinite or definite article is used when referring to a singular noun, e.g. “a”, “an”, “the”, this includes a plural of that noun unless something else is specifically stated.

Furthermore, the terms first, second, third and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described of illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the present description and claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

FIGS. 1 to 3 have already been described in the introductory part of the description.

In FIG. 4, the development over time of the target-dependent sensor signals S₁ and S₂ for two different test samples is shown. The signal strength depends on the target concentration, in a way that depends on the type of assay. E.g. in a sandwich assay, signal S₁ corresponds to a low target concentration and signal S₂ corresponds to a high target concentration. The opposite applies in the example of an inhibition or competition assay (i.e. signal S₁ corresponds to a higher target concentration than signal S₂). Over a time interval tₘ, which corresponds to the measurement time, is possible to measure the target concentrations with sufficient accuracy. Several small circles in FIG. 4 denote measures actually performed by the sensing device. The time interval tₘ corresponds to the time-to-result of the sensing device. At the beginning of the measurement time interval is the arrival time t_{w} of the fluid, especially a liquid, above the sensing surface. Note that the figure gives an example of a more or less linear behavior of the signal versus time. In some cases the signal can be more complicated, e.g. like a higher order polynome, due to for example an activation time of the biological layer, or a diffusion time or drift time of beads toward the sensor surface.

Magnetic biosensors are generally made to be as sensitive as possible to beads specifically bound to the sensor surface. However, the measurement of the concentration of specifically bound beads (or labels) to the surface can be perturbed by the presence of unbound or non-specifically bound beads (or labels). Therefore, a reliable data point for measuring a target concentration through a label concentration is preferably taken when unbound and/or non-specifically bound beads are removed from the surface.

Therefore, the following sequence or cycle can be applied, once or in a repeated manner:

pull the beads towards the surface; thereby binding may take place

then the beads can be moved away from or aside of the sensor surface, to distinguish between specific binding to the surface and non-specific binding or unbound beads.

after this displacement step one can measure the actual signal of specifically bound beads.

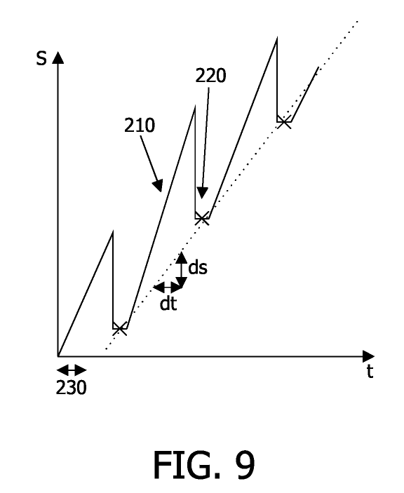

FIG. 9 sketches the signal of a sensor that is sensitive to labels bound to the surface and is also to a certain extent sensitive to unbound beads in the vicinity of the sensor surface. The signal is sketched as a function of time and it is described how the slope of the surface-binding curve can be derived. In the context of the present invention, the surface-sensitive signal is also called the raw signal of the target-dependent sensor signal S (or S₁, S₂ depicted in FIG. 4). The above-mentioned sequence or cycle is used to determine the slope of the surface-sensitive signal represented by the dotted line. The signal represented by the dotted line is identical to the target-dependent sensor signal S. Therefore, the measured slope of this signal leads to a determination of the target concentration in the fluid sample. The above mentioned sequence or cycle is also represented in FIG. 9, where reference sign 210 denotes the step of allowing labels near the surface or pulling labels to the surface, and where reference sign 220 denotes the step of removing labels or pulling labels from the surface. Reference sign 230 denotes a single sample interval or a “unitary measurement” event in the manner of the small circles in FIG. 4. During the measurement time tₘ (cf. FIG. 4), a certain number of such sample intervals are necessary to collect.

The signal during the step denoted by reference sign 210 is caused by beads binding to the sensor surface as well as by unbound beads in the vicinity of the sensor surface. Using the signals during the steps denoted by reference signs 210 and 220, the surface-bound signal as well as signal due to unbound beads can be derived. As a result, the concentration of labels in the solution as well as the concentration of labels bound to the sensor surface can be derived. According to the present invention, these two measurements lead to a very accurate determination of the target concentration in the fluid.

The slope of the curve is proportional to the binding rate of labels to the sensor surface. The average slope dS/dt of the signal during the measurement time tₘ is given by the signal S (at the end of tₘ) devided by the measurement time tₘ. The target concentration is related to the binding rate, in a fashion that depends on the assay. The target concentration can be very accurately determined when the signal is recorded with a high signal-to-noise ratio. In the case of detection by a magneto-resisitve biosensor, a high signal-to-noise ratio can be achieved by the use of high currents. High currents can cause heating or irreversibly change bio-materials. However, when signals are measured at the endpoint of the assay, heating and changes of the biomaterials are not important. In other words, endpoint signals (i.e. specifically bound labels and/or unbound labels in the solution in the vicinity of the binding sites) can be measured with a very high signal-to-noise ratio, which enhances the precision of a determination of the target concentration.

In FIG. 5, a system 35 and a sensing device 10 is shown. The present invention provides a sensing device 10 such as, e.g. a biosensor or a biochip, especially suitable to use as a biosensor-array, i.e. a multitude of biosensors arranged on one single substrate material. The sensing device 10 is part of a system 35 according to the present invention. In a preferred application of the sensing device 10 of the present invention, the sensing device 10 is used in a test kit for road-side through-the-window testing of drugs-of-abuse in saliva for traffic safety. By way of example, this device is equipped for a competitive assay (cf. FIG. 2b). The sensing device 10 comprises a sensing surface 1 where binding sites 2 are located. The binding sites 2 are provided to specifically bind to capture molecules 3 targets 6. The targets 6 are biological entities (e.g. drugs of abuse) and the capture molecules 3 are target-like molecules that have been coupled to the labels 4. Entities 3 and 6 can both bind to sites 2, therefore this is called a competitive assay format. The device can also be equipped for an inhibition assay (cf. FIG. 2c) but for the sake of simplicity, only the case of a competitive assay is explained in this paragraph. The sensing device 10 comprises a substrate 20. It is preferred but not mandatory that the sensing device 10 comprises magnetic field generating means 13. At least if no magnetic field generating means 13 are provided in the substrate 20 of the sensing device 10, a magnetic field generating device 40 external to the sensing device 10 is usually present with the inventive system 35. The system 35 further comprises a housing 21 forming at least a channel or chamber 22 or the like for providing sufficiently space for the fluid 5, especially a liquid, containing the target-like capture molecules 3 attached to the labels 4. Furthermore, the fluid 5 comprises the targets 6.

In another preferred embodiment, the device of FIG. 5 is equipped for an inhibition assay format (cf. FIG. 2c). In that case the binding sites 2 are target-like molecules coupled to the sensor surface 1, The targets 6 are biological entities such as drugs of abuse or the like and the capture molecules 3 are biological entities (e.g. anti-target antibodies) that can specifically bind to targets 6 and target-like binding sites 2. This is called an inhibition assay format because the binding of targets 6 to labels 4 partially or totally inhibits the binding of label 4 to the target-like binding sites 2.

As is clear from the above two examples, the device can be equipped for a range of different assay formats, e.g. competitive, inhibition, displacement, sandwich assay. As is known in the art, the biochemical and chemical species (e.g. targets, target-like molecules, labels, binding sites) can be brought together at once or sequentially. For enhanced speed, it is advantageous to bring the reagents together at once. In the latter case, the kinetics of the processes and the factual sequence of binding processes depends e.g. on the diffusion and binding speeds.

Note that the sensor or chip substrate can be any suitable mechanical carrier, of organic or inorganic material, e.g. glass, plastic, silicon, or a combination of these. In a preferred embodiment of the sensing device 10, an electronic circuit 30 is provided in the substrate 20. The electronic circuit 30 is provided to collect signals or data collected or measured by a magnetic sensor element 11 located in the substrate 20. In an alternative embodiment of the present invention, the electronic circuit 30 can also be located outside the substrate 20.

In FIG. 6, a schematic representation of a first embodiment of the sensing element 10 is shown. In the substrate 20 is located the sensing surface 1 and the magnetic sensor element 11. Furthermore, a magnetic field generating means 13 is located in the substrate 20 of the sensing element 10. The magnetic field generating means 13 creates a magnetic field 130. If an external magnetic field generating means 40 (cf. FIG. 5) is present, the aforementioned magnetic field 130 will be a component of the resulting magnetic field created by the magnetic field generating means 30 together with the external magnetic field generating means 40.

The magnetic field generating means 13 may, for example, be magnetic materials (rotating or non-rotating) and/or conductors such as, e.g. current wires 13. In the embodiment described, the magnetic field generating means 13 is preferably generated by means of current wires. Detection of rotational and/or translational movement of labels 4 may preferably be performed magnetically. In the first as well as the following embodiments of the present invention, the magnetic detection may preferably be performed by using the integrated magnetic sensor element 11. Various types of sensor elements 11 may be used such as, e.g. a Hall sensor, magneto-impedance, SQUID, or any of the suitable magnetic sensor. The magnetic sensor element 11 is preferably provided as a magnetoresistive element, for example, a GMR or a TMR or an AMR sensor element 11. A rotating magnetic field generating means can be provided by means of current wires as well as current generating means integrated in the substrate 20 of the sensing device 10. The magnetic sensor element 11 may have, e.g., an elongated (long and narrow) strip geometry. The rotating magnetic field is thus applied to the magnetic labels 4 by means of current flowing in the integrated current wires. Preferably, the current wires may be positioned in such a way that they generate magnetic fields in the volume where magnetic labels 4 are present.

In FIG. 7, a schematic representation of a second embodiment of the sensing element 10 is shown. In the substrate 20 is located the sensing surface 1 and the magnetic sensor element 11. The sensing surface 1 comprises as a distinguishing means a first and second surface area designated commonly by reference sign 14. Individually, the first and second surface area are designated by reference signs 141 and 142 respectively.

In FIG. 8, a schematic representation of a third embodiment of the sensing element 10 is shown. In the substrate 20 is located the sensing surface 1 and the magnetic sensor element 11. Furthermore, a first magnetic field generating means 131 and a second magnetic field generating means 132 is located in the substrate 20 of the sensing element 10 creating together magnetic field 130. In addition, the sensing surface 1 comprises as a further part of the distinguishing means a first and second surface area designated commonly by reference sign 14. It can be seen in FIG. 8 that at the location of the magnetic sensor element 11, the components of the magnetic fields created by the first and second magnetic field generating means 131, 132 compensate, at least in respect of a component of the resulting magnetic field for which the magnetic sensor element 11 is sensitive.

The applied magnetic field 130 is such that it generates a torque on the labels 4. In that way, the labels 4 are rotated with respect to another body (e.g. another label 4, the sensing surface 1, etc) using the magnetic field 130. As previously stated, the labels 4 contain a magnetic material known in the art. The label 4 may, for example, be a magnetic bead, a magnetic particle, a magnetic rod, a string of magnetic particles or a magnetic material inside a non-magnetic matrix. A parameter relating to the rotational or motional freedom of the labels 4 can be detected by the sensing device 10. The method according to the invention allows high-frequency motional freedom or rotational freedom measurements. By way of measurements of this kind, a distinction between specifically attached versus non-specifically attached biological entities 3 is possible and thereby a detection of the different concentrations of the labels 4 bound in a different way to the sensing surface 1.

Another possibility to determine the different concentrations of specifically attached versus non-specifically attached biological entities 3 is to provide a gradiometer-like configuration of the sensing surface 1 operating with at least a first and a second surface area 141, 142. By providing such a structure in the sensing surface 1, it is possible to derive additional information relating to the surface concentration of magnetic labels 4. This is explained in more detail in international patent application WO 03/054566 which is incorporated here by reference regarding the following matters:

Structure of the sensing surface 1 with at least a first surface area and a second surface area in order to determine the volume density of magnetic labels 4 and/or the areal density of magnetic labels 4 according to the first, second and third embodiment,

Method of measuring the volumetric density and areal density of magnetic labels 4.

In this invention, emphasis was put on the application of the invention in immunoassays. It will be clear to a person skilled in the art that also assays with other targets and other binding entities can be used, e.g. assays with nucleic acids and hybridizing entities.

We note that the above invention can be combined with sensor multiplexing and/or label multiplexing. In sensor multiplexing, sensors are used with different types of binding sites 2. Also the capture molecules 3 on the labels 4 can be of different types. In label multiplexing, different types of labels 4 are used, e.g. labels with different sizes or different magnetic properties.

1. A sensing device (10) for determining the concentration of at least one sort of targets (6) in a fluid (5) containing at least one sort of polarizable or polarized magnetic labels (4),
the sensing device (10) comprising at least one sensing surface (1),
the sensing surface (1) comprising at least partially at least one sort of binding sites (2) capable to specifically attach to at least one sort of biological entities (3) linked to the magnetic labels (4),
the sensing device (10) further comprising at least one magnetic sensor element (11),
the sensing device (10) further comprising distinction means (12) for time-resolved distinguishing between magnetic labels (4) specifically attached to the binding sites (2) versus the exposure rate of unbound labels (4) to the binding sites (2).

2. A sensing device (10) according to claim 1, wherein the exposure rate of unbound labels to the binding sites (2) is determined via the concentration of unbound labels (4) in the fluid in the vicinity of the binding sites (2).

3. A sensing device (10) according to claim 1, wherein the distinction means (12) comprise magnetic field generating means (13) for generating a magnetic field (130).

4. A sensing device (10) according to claim 1, wherein the distinction means (12) comprise two magnetic field generating means (131, 132) positioned at each side of one magnetic sensor element (11).

5. A sensing device (10) according to claim 3, wherein the magnetic field generating means is a two-dimensional wire structure located on the sensing device (10).

6. A sensing device (10) according to claim 3, wherein the magnetic field generating means (13) generates a rotating magnetic field (130).

7. A sensing device (10) according to claim 3, wherein the magnetic field generating means (13) generates a unidirectional magnetic field (130).

8. A sensing device (10) according to claim 1, wherein the distinction means (12) comprise a first surface area (141) in a first level and a second surface area (142) in a second level, wherein the magnetic sensor element (11) being positioned near a transition (143) between the first and the second surface area (141, 142) and facing at least one of the surface areas (141, 142).

9. A sensing device (10) according to claim 8, wherein the magnetic sensor element (11) is centered around the transition (143) seen in substantially perpendicular projection.

10. A sensing device (10) according to claim 3, wherein the distinction means (12) comprise a capacitive sensor means.

11. A sensing device (10) according to claim 1, wherein the magnetic sensor element (11) is a magnetoresistive sensor element, preferably an AMR, a GMR or a TMR sensor element.

12. A sensing device (10) according to claim 1, wherein the magnetic labels (4) are provided as magnetic beads.

13. A system (35) for determining the concentration of at least one sort of targets (6) in a fluid (5) containing at least one sort of polarizable or polarized magnetic labels (4), the system (35) comprising the magnetoresistive sensing device (10) according to claim 1.

14. A system (35) according to claim 13, further comprising an electronic circuit (30) for detecting a change in magnetoresistance of the magnetic sensor element (11), the electronic circuit (30) being present in the substrate (20) or outside the substrate (20).

15. A system (35) according to claim 13, further comprising external magnetic field generating means (40) for generating a magnetic field.

16. A method for determining the concentration of at least one sort of targets (6) in a fluid (5) containing at least one sort of polarizable or polarized magnetic labels (4) using the sensing device (10) of claim 1, the method comprising the steps of:
providing a fluid (5) comprising at least one sort of magnetic labels (4) over the sensing surface (1),
applying a magnetic field (130),
time-resolved distinguishing between magnetic labels (4) specifically attached to the binding sites (2) versus labels (4) non-specifically attached.

17. A method according to claim 16, wherein the concentration of targets (6) is determined by calculating the ratio of the concentration of labels (4) specifically attached versus the concentration of labels (4) not attached.

18. A method according to claim 16, wherein the concentration of targets (6) is determined by calculating the ratio of the measured specific binding rate of at least one sort of labels (4) to the binding sites (2) versus the measured exposure rate of labels (4) to the binding sites (2), whereby it is preferred to determine the exposure rate by measuring the concentration of unbound labels (4) in the fluid in the vicinity of the binding sites (2).

19. A method according to claim 16, wherein the time-resolved distinguishing between magnetic labels (4) specifically attached to the binding sites (2) versus labels (4) non-specifically attached is performed using the difference of rotational and/or translational mobility of labels (4) specifically attached versus labels (4) non-specifically attached.

20. A method according to claim 16, wherein the time-resolved distinguishing between magnetic labels (4) specifically attached to the binding sites (2) versus labels (4) non-specifically attached is performed using at least one modulated magnetic field (130).

21. A method according to claim 16, wherein the specific attachment of the targets (4) to the binding sites (2) is obtained by way of an inhibition format assay.

22. A method according to claim 16, wherein the specific attachment of the targets (4) to the binding sites (2) is obtained by way of a competition format assay.

23. A method according to claim 16, wherein the specific attachment of the targets (4) to the binding sites (2) is obtained by way of a sandwich format assay.

24. A method according to claim 16, wherein the specific attachment of the targets (4) to the binding sites (2) is obtained by way of an anti-complex format assay.

25. A method according to claim 16, wherein the specific attachment of the targets (4) to the binding sites (2) is obtained by way of a blocking agent format assay.
